(19) United States
(12) Patent Application Publication
(10) Pub. No.: US 2005/0028062 A1
(43) Pub. Date: Feb. 3, 2005

(54) Test method and apparatus for high-speed semiconductor memory devices

(76) Inventors: Konrad Herrmann, Muenchen (DE); Andreas Schellinger, Muenchen (DE); Peter Mayer, Neubiberg (DE); Markus Rohleder, Muenchen (DE)

Correspondence Address: SLATER & MATSIL LLP, 17950 PRESTON ROAD, SUITE 1000, DALLAS, TX, 75252, US

(21) Appl. No.: 10/834,275

(22) Filed: Apr. 29, 2004

(30) Foreign Application Priority Data
Apr. 30, 2003 (DE) 103 19 516.5

(51) Int. Cl. G06F 11/00; G01R 31/28; G06F 7/02; H03M 13/00

(52) U.S. Cl. 714/736

(57) ABSTRACT

For testing high-speed semiconductor memory devices with a high data transfer rate (such as DDR-DRAMs), in receiving units of supply and handling systems for tester apparatuses, selected graphic controllers are arranged on test assemblies, which are substantially structurally identical to graphics cards, and are connected via connecting lines to test receptacles for receiving the DRAMs. Components of the DRAMs that determine the data transfer rate thereof are tested by means of the graphic controllers at the supply and handling system.

### BACKGROUND

1. Field of the Invention

The present invention relates to a test method for semiconductor memory devices arranged in test receptacles of a receiving unit by means of a supply and handling system from which data signals are output and evaluated by means of a test apparatus. The invention furthermore relates to a test apparatus for carrying out the test method.

2. Background

A customary conventional test set up for high-volume testing of semiconductor memory devices comprises an automated tester apparatus and a supply and handling system (handler). By means of the supply and handling system, the semiconductor memory devices to be tested are taken from a magazine and pressed into test receptacles for electrical contact-connection in a manner free of soldering. During testing, the supply and handling system sets and monitors ambient conditions under which the test is to be carried out, for instance an ambient temperature. After testing, the tested semiconductor memory devices are sorted by the supply and handling system in accordance with a test result. The tester apparatus is generally arranged to be set apart from the supply and handling system in the test construction, test signals required for testing the semiconductor memory devices being generated and data signals output during testing by the semiconductor memory devices to be tested being evaluated in said tester apparatus.

For this purpose, electrical connecting lines are led from the tester apparatus to a test head assigned to the supply and handling system. A receiving unit (e.g., Hifix) carrying the test receptacles imparts an electrical connection between the semiconductor memory devices to be tested (also referred to herein as “devices under test”), which are arranged in the test receptacles, and an interface to the test head that is not specific to devices under test. The test receptacles are adapted to a housing form of a respective type of semiconductor devices to be tested. The receiving unit usually has only a wiring specific to devices under test between the test receptacles and the interface to the test head.

The performance requirements of the test set ups of the type described above increase as the speed of the semiconductor devices to be tested increases. Presently, clock frequencies of 600 MHz are realized on graphics cards for PCs with respect to a data transfer rate between a graphic memory and a graphic controller which manages image data stored in the graphic memory. A data rate of 1200 Mbits/sec then results per data signal for semiconductor memory devices with a DDR interface (DDR-DRAMs, double data rate dynamic random access memories). Testing the timing behavior, in particular, of data signals of such high-speed semiconductor memory devices requires a higher internal clock for the tester apparatuses, in order that the data signals output by the semiconductor memory devices are temporally resolved with sufficient accuracy. A time expenditure required for developing and testing such tester apparatuses has the effect that, initially, no suitable tester apparatuses are available for a relatively long period of time for in each case what are actually the fastest semiconductor memory devices.

A further problem encountered with conventional semiconductor memory device test set ups is that of preserving the signal integrity of the test and data signals transferred between the tester apparatus and the test head or the test receptacles.

At the present time, tester apparatuses or test set ups for high-volume testing of high-speed semiconductor memory devices with a clock frequency of more than 533 MHz are expensive and have limited availability.

FIG. 1 schematically illustrates a test apparatus that is customary at the present time for testing semiconductor memory devices 1. In this case, the test apparatus 3 comprises an automatic supply and handling system 2, which supplies the semiconductor memory devices 1 to be tested to test receptacles 10. During the test, the supply and handling system 2 controls the ambient parameters necessary for the test, in particular the ambient temperature. After the test, the semiconductor memory devices 1 are sorted depending on an individual test result by means of the supply and handling system 2. Generation of binary test signals or test data and evaluation of data signals output by the semiconductor memory devices 1 are effected in a remote tester apparatus 30. The test program executed in the tester apparatus 30 controls the supply and handling system 2 via a control bus CP. Via a test signal bus TS, test or test data signals are transferred between the tester apparatus 30 and a test head 21 assigned to the supply and handling system 2. A receiving unit 4 is provided on the test head 21, and forms an electrical and mechanical interface between the test receptacles 10, which are specific to devices under test, and the test head 21, which is not specific to devices under test. In the region of the receiving unit 4, the test signal bus TS is routed to the test receptacles 10.

When testing high-speed semiconductor memory devices with clock frequencies above 500 MHz, interventions in the region of the test signal bus TS always require a renewed calibration of the test apparatus 3.

Accordingly, there is a need to provide improved testing set ups and methodologies, especially as clock frequencies continue to increase.

### SUMMARY

The present invention provides a test method that enables high-volume testing of high-speed semiconductor memory devices in accordance with the specifications of the high-speed semiconductor memory devices and with a minimum of losses of yield attributable solely to the test environment. Furthermore, the invention provides a test apparatus that makes such a test method possible.

Specifically, the present invention provides a test method for semiconductor memory devices, including arranging a plurality of the semiconductor memory devices in test receptacles of a receiving unit by using a supply and handling system, and then causing the semiconductor memory devices to output data signals. The data signals are then evaluated using a test apparatus having test control units that are selected from memory control units, wherein the test control units are a part of the test apparatus.

The present invention is also directed to a test apparatus for testing semiconductor memory devices that are provided together with memory control units for operation on memory assemblies and include a data strobe terminal for a data strobe signal and data terminals for bi-directional data signals. The test apparatus includes at least one test receptacle for receiving a respective one of the semiconductor memory devices in a manner free of soldering, a supply and handling system for automated population of the test receptacles with the semiconductor memory devices to be tested, a receiving unit, which imparts a mechanical and electrical interface between the test receptacles and the supply and handling system, test signal units for outputting, for reception and for evaluation of data signals output by the semiconductor memory devices, and test control units having substantially the same design as the memory control units and being operable as test signal units.

Other and further objects, features and advantages of the invention will appear more fully from the following description.

### BRIEF DESCRIPTION OF THE DRAWINGS

In the following the invention is explained in more detail with reference to the accompanying figures in which

FIG. 1 shows a schematic illustration of a conventional test apparatus,

FIG. 2 shows a schematic illustration of a test apparatus according to the invention according to a first exemplary embodiment with a multiplexer unit,

FIG. 3 shows a schematic illustration of a second exemplary embodiment of the test apparatus according to the invention with a plurality of motherboards integrated in a receiving unit, and

FIGS. 4A and 4B shows a plan view and a cross section through a receiving unit according to the first exemplary embodiment of the test apparatus according to the invention, in a simplified illustration.

### DETAILED DESCRIPTION

Embodiments of the present invention will be described in detail below with reference to the accompanying drawings. The following reference symbols and abbreviations are used herein.
1 Semiconductor memory device
10 Test receptacle
11 Receptacle unit
2 Supply and handling system
21 Test head
3 Test apparatus
30 Tester apparatus
31 Data processing apparatus
32 Screen
33 Keyboard
4 Receiving unit (Hifix)
4′ Modified receiving unit (Hifix)
4″ Modified receiving unit (Hifix)
41 Multiplexer unit
43 Test assembly
44 Test control unit
451 First motherboard
452 Motherboard
46 Coupling bus
47 Controllable voltage source
5 Quasi-graphics card
AG Graphic interface
AG′ Multiplied graphic interface
CP Control bus
TS Test signal bus
TS′ Modified test signal bus

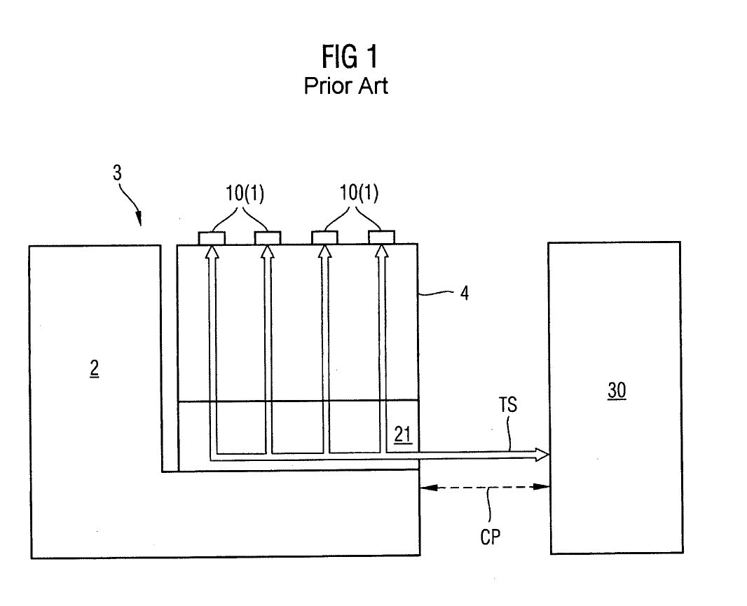

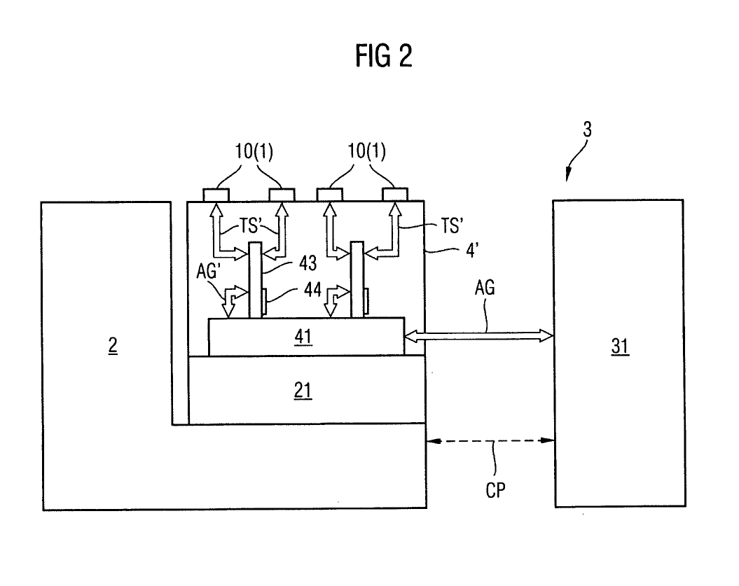

FIG. 2 reveals (in comparison to test signal bus TS of FIG. 1) that a test signal bus TS′ modified according to the invention is significantly non critical in comparison. The test apparatus according to the invention as illustrated in FIG. 2 has a modified receiving unit 4′ with a plurality of graphics cards 43 connected to a multiplexer unit 41. Graphic controllers 44 are provided on the graphics cards 43. The installation locations provided for semiconductor memory devices 1 on the graphics cards 43 are connected to the test receptacles 10. The graphics cards 43 are arranged within the modified receiving unit 4′ in such a way that the connecting lines to the test receptacles 10 respectively assigned to a graphics card 43, which connecting lines form the modified test signal bus TS′, are as short as possible and, as practicably possible, of the same length. The semiconductor memory devices 1 placed in the test receptacles 10 are tested by means of a test program which is executed at least partially in the graphic controllers 44. The graphic controllers 44 are controlled by a super-ordinate data processing apparatus 31 via a standardised graphic interface, for instance via an accelerated graphic port, AGP. The graphic interface is multiplied for the data processing apparatus 31 by the multiplexer unit 41, which, for its part, is connected to the graphics cards 43. The control of the supply and handling system 2 in the course of a test program executed in the data processing apparatus 31 is effected via a control bus CP connected to a standardised interface of the data processing apparatus 31.

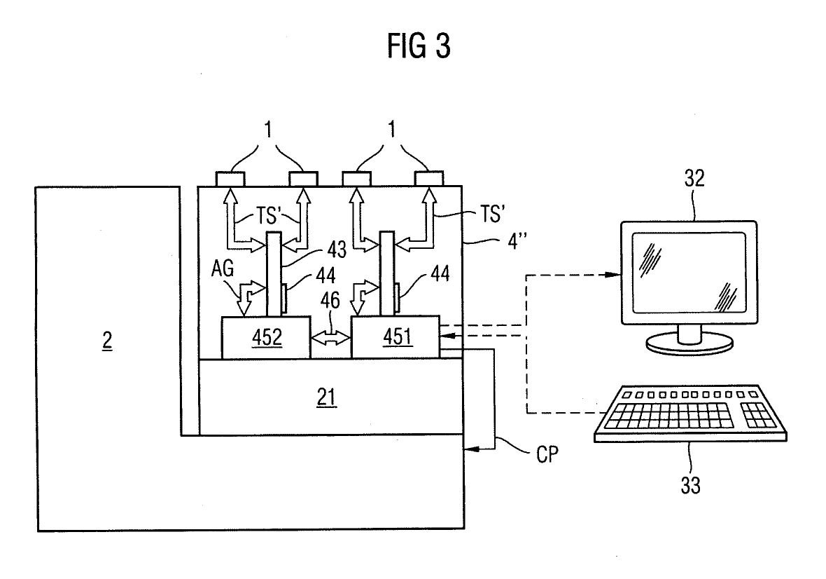

A further embodiment of the test apparatus according to the invention is illustrated in FIG. 3. In contrast to the test apparatus shown in FIG. 2, each test assembly or graphics card 43 is arranged in a motherboard 451, 452. In this case, a first motherboard 451 is formed as a data processing apparatus which provides interfaces for process visualization, for instance for a screen, for a user intervention in the test sequence, for instance for a keyboard, and also for control of the supply and handling system 2. Further motherboards 452 are connected to the first motherboard 451 via a coupling bus 46.

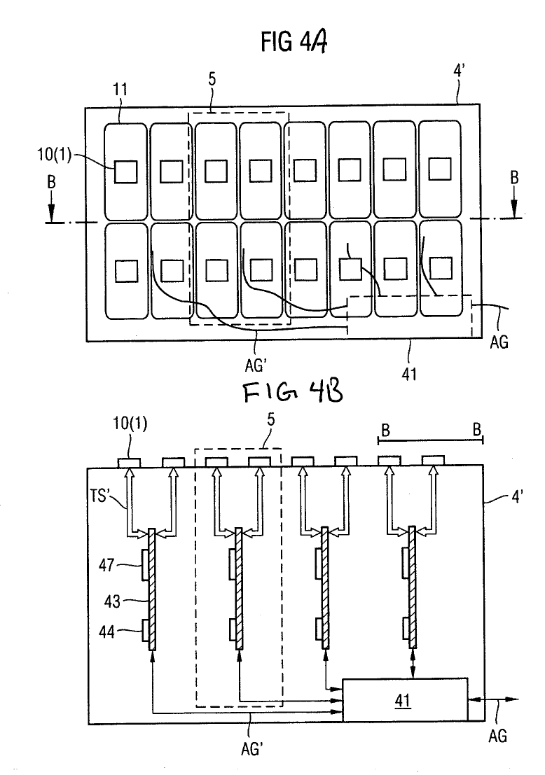

A modified receiving unit 4′ is shown in plan view of FIG. 4A. A respective receptacle unit 11 of the modified receiving unit 4′ is assigned a test receptacle 10 for population with a semiconductor memory device 1. A multiplexer unit 41 for multiplying the graphic interface is arranged inside the modified receiving unit 4′. The multiplexer unit 41 is connected to a data processing apparatus (not shown) by an AGP bus AG. The multiplexer unit 41 outputs signals received via the AGP bus AG in parallel via the multiplex AGP bus AG′ to quasi-graphics cards 5.

A configuration of the quasi-graphics cards 5 can be gathered from the cross section through the modified receiving unit 4′ as shown in FIG. 4B. A quasi-graphics card is an essentially conventionally available graphics card 43 with a graphic controller 44 operated as a test control unit. In addition, the graphics cards 43 have voltage sources 47, which are controlled either by the graphic controller 44 or directly via the AGP bus AG or AG′. The installation locations for a video memory of the graphics cards 43 are not populated. Instead, the graphics cards 43 are connected to the test receptacles 10 by connecting lines, the connecting lines forming a modified test signal bus TS′. The semiconductor memory devices 1 to be tested are driven via the graphic controllers. The test program is programmed at the PC, for instance at DOS level, and transferred in part via the AGP bus AG to the graphic controllers 44. In the course of the test program, patterns for test data, the clock frequency, signal and trigger levels and also an offset of signal edges with respect to one another are altered. The ambient temperature is controlled by the supply and handling system 2. The supply voltages, for instance VDD for supplying internal circuits of the semiconductor memory devices and VDDQ for supplying output drivers, are set according to the specifications by means of a controllable voltage supply 47 in the course of testing. Each graphic controller 44 tests the semiconductor memory devices 1 assigned to it in parallel and passes information about failures to the data processing apparatus 31.

Thus, as will be appreciated by those skilled in the art, the test method according to the invention relates to high-speed semiconductor memory devices which are suitable in their intended application for joint operation with a memory control unit on a memory assembly. In this case, a plurality of the semiconductor memory devices to be tested are in each case supplied to test receptacles of a receiving unit by means of a supply and handling system. The receiving unit forms a mechanical and electrical interface between the semiconductor memory device and the supply and handling system. In the test receptacles, the semiconductor memory devices are contact-connected in a manner free of soldering. For testing, data signals are output by the semiconductor memory devices and are evaluated by means of a test apparatus.

According to the invention, from a plurality of identical memory control units (memory controller, graphic controller) provided in each case for operation with the semiconductor memory device, suitable memory control units are now selected as test control units and provided as part of a test apparatus. The test control units provided as part of the test apparatus then receive and evaluate the data signals output by the semiconductor memory devices to be tested.

A test, in particular, of the functional units which determine the high-speed properties of the semiconductor memory devices (e.g., of output drivers for data signals), is not effected on conventional high-speed tester apparatuses. The present invention however, provides an integration of circuitry borrowed from a contemporary application into a test environment suitable for high-volume testing of the semiconductor memory devices. This enables a regular adaptation of the testability of an upper speed limit of the semiconductor memory devices to be tested to the clock frequency provided by the application and adapts a functional test to a test construction adapted for high-volume testing of the semiconductor memory devices.

On known tester apparatuses, which at the present time operate at an internal frequency of 500 MHz at their specification limit, it is not possible to ascertain an actually higher maximum operating frequency of a high-speed semiconductor memory device.

The invention furthermore utilizes the properties and resources of customary memory control units. An internal clock frequency of memory control units (e.g., graphic controllers) embodied using logic technology, is usually higher than the clock frequency provided for the data transfer to the semiconductor memory device. The internal clock frequency and time intervals between signal edges of critical signals are programmable to a limited extent for the purpose of testing the graphic controller and for adapting the graphic controller to a circuitry. According to the invention, the properties of the memory control units are utilized to the effect that data signals, for instance, are output such that they are suitable for testing the high-speed semiconductor memory devices.

In accordance with the test method, in a known manner, suitable test data are generated in the test apparatus and transferred to the semiconductor memory devices. The test data are stored in the semiconductor memory devices. In the further course of testing, the test data are output as test data signals, from which the test control units derive test data. The test data are evaluated by the test control units by a comparison with the test data.

The receiving unit is provided for receiving the test receptacles and the test control units. In this case, it is particularly advantageous that a test bus formed from a plurality of data signal lines for the bi-directional transfer of data signals between the semiconductor memory devices to be tested and the test apparatus is significantly shortened. This makes it easier to preserve signal integrity, in particular of the high-speed signals on the test bus, compared with conventional test systems, which generally require complicated calibration measures.

Periodic calibration runs are generally prescribed for tester apparatuses, in the course of which the test signals output by the tester apparatus are continuously adjusted with regard to their timing behavior, their level and their propagation time on the test signal lines. Since a signal propagation time on a test signal line can change upon each intervention in the signal path of the test signals, renewed calibration is necessary after every such intervention, for instance a new installation of a receiving unit or a reactivation of a system part after a shut down time. Since, according to the invention, the test bus is formed only in the receiving unit, the number of possible triggers for a calibration is reduced. Furthermore, a tester apparatus is not absolutely necessary for the calibration and, therefore, does not necessarily entail an outage time of a tester apparatus.

A test program which controls the outputting of the test data by the test control units, the reading back thereof from the semiconductor memory devices, and also the assessment thereof in the test control units advantageously runs independently of a tester apparatus. For this purpose, according to a first preferred embodiment of the method according to the invention, a test program for the test control unit is in each case stored in a memory control program memory assigned to the test control unit.

According to a further preferred embodiment of the method according to the invention, the test control units are provided on test assemblies, which are essentially structurally identical to the memory assemblies from the application. In this case, the contact devices of installation locations which are provided on the test assemblies for the installation of semiconductor memory devices of the type of the semiconductor memory devices to be tested are connected to respectively assigned contact devices of the test receptacles. The test assemblies are equipped with the test control units and arranged in the receiving unit. Furthermore, at least one data processing apparatus is provided and connected to the test assemblies and the supply and handling system. Under the control of a test program stored in the data processing apparatus, ambient parameters of the test are prescribed in the course of a test of the semiconductor memory devices by means of the supply and handling system. The test program of the data processing apparatus controls the transfer of the test data and the evaluation of the test data directly or indirectly by means of the memory test program stored in the memory control program memories. The semiconductor memory devices are tested with regard to the supply voltage specifications by means of voltage sources for operating the semiconductor memory devices, which voltage sources can be controlled by the data processing apparatus or the test control units.

Signal and trigger levels, in particular of the data signals, are tested by means of a corresponding programming of the test control units. The possibility for this results, in a manner similar to that above, from the fact that in customary memory control units such as graphic controllers, for instance, for the purpose of adapting the memory control unit to different environments, both the trigger level for received signals and the signal level for output signals can be programmed to a limited extent. If the trigger or signal levels which are necessary for the specification of the semiconductor memory devices cannot directly be set sufficiently accurately by means of a corresponding programming of the graphic controllers, then a test temperature is preferably chosen in such a way that a test carried out with a test level for signal or trigger levels at the test temperature is essentially equivalent to a test with the specified levels at the specified ambient temperature. In this case, it is advantageous for the semiconductor devices that are to be tested to be thermally decoupled from the test assemblies by the operation of fans provided in the receiving unit.

The semiconductor memory devices are preferably tested with regard to sufficient time margins in that, in a first step, the timing behavior of the test control units is determined. In a second step, a test frequency is determined, at which the semiconductor memory devices which are to be assigned to a predetermined speed sorting are to be tested taking account of the measured timing behavior of the respective test control units, in order to reliably comply with the specifications of the predetermined speed sorting. Finally, the test for semiconductor memory devices which are to be assigned to the predetermined speed sorting is carried out at the test frequency. The data transfer from and to the semiconductor memory devices to be tested is effected at the test frequency.

A further preferred embodiment of the method according to the invention relates, in particular, to semiconductor memory devices with an interface for doubling the data transfer rate (DDR-IF, double data rate interface). If a write or read access is in each case effected at the rising or falling edge of a clock signal in the case of conventional, synchronous semiconductor memory devices (SDRAMS, synchronous dynamic random access memories), data are transferred both from the falling edge and on the rising edge of the clock signal in the case of DDR-DRAMS (double data rate dynamic random access memories). This results in a doubling of the data transfer rate for the same clock frequency. A signal “data query strobe” DQS from the customary clock signal CLK is used for synchronizing the actual data transfer from and to a semiconductor memory device with DDR-IF. DQS corresponds to a data strobe signal which, during the reading of data from a semiconductor memory device, is generated in a manner analogous to the data signals DQ from the semiconductor memory device and, during the writing of data to the semiconductor device, is generated in a manner corresponding to the data signals DQ from the memory control unit.

During the writing of data to the semiconductor memory device, DQS is controlled in such a way that each edge of DQS indicates the center of a transferred data bit at DQ. The semiconductor memory devices with DDR-IF accept the data on DQ in each case at the instant of an edge at DQS. During reading from the semiconductor memory device, DQS is generated edge-synchronously with the data DQ. The memory control unit expects the data on the data lines after each edge at DQS.

During the read-out of data from the semiconductor memory device, conventional tester apparatuses assess a data signal synchronously with a read operation controlled by the tester apparatus itself. In the application, however, a higher data transfer rate between the semiconductor memory devices and the memory control unit is made possible precisely by the synchronization of the data transfer with the data strobe signal. However, a speed sorting of the semiconductor memory devices, which takes account of this advantage, is not actually possible by means of conventional tester apparatuses. Since a speed selection of the semiconductor memory devices with a DDR interface is preferably effected by a memory control unit operated as a test control unit, it is possible to sort the semiconductor memory devices in accordance with their actual maximum frequency. A proportion of semiconductor memory devices which can be assigned to a higher speed sorting is advantageously increased in this way.

The test apparatus according to the invention is provided for testing semiconductor memory devices which are suitable together with a memory control unit for operation on memory assemblies. In particular, the test apparatus is suitable for testing semiconductor memory devices having a data strobe terminal for a data strobe signal and data terminals for the bi-directional transfer of data signals synchronously with the data strobe signal. In an initially known manner, the test apparatus comprises at least one test receptacle for receiving a respective one of the semiconductor memory devices in a manner free of soldering, a supply and handling system for populating the test receptacles with the semiconductor memory devices to be tested and also for controlling ambient parameters, for instance the ambient temperature, under which the test is to be performed, and a test signal unit suitable for generation, for transfer, for reception and for assessment of the data carrier signal and of the data signals. According to the invention, the test apparatus has, as test signal units, test control units which are essentially structurally identical to the memory control units.

Preferably, a respective test control unit is arranged on a test assembly which is essentially structurally identical to a memory assembly. Furthermore, the test apparatus has connecting lines between contact devices of installation locations—provided on the test assembly—for the semiconductor memory devices and respectively assigned contact devices of the test receptacles.

In a particularly advantageous manner, the test assemblies are arranged in a receiving unit which forms an electrical and mechanical interface between the test receptacles and the supply and handling system.

The test assemblies arranged in the receiving unit are connected to a data processing apparatus. For its part, the data processing apparatus is connected to the supply and handling system. A PC is preferably used as the data processing apparatus. The control of the supply and handling system is generally not critical with respect to time and is effected via one of the customary PC interfaces. The test signals for the semiconductor memory devices to be tested are controlled by the test control units, which are provided in each case in the manner of a graphic controller on the test assemblies embodied as graphics cards. The control of the graphic controllers is effected via a standardized interface for graphics cards, for instance an accelerated graphic port, AGP. The test program according to which the test control unit performs the test of the semiconductor memory devices is stored either in the data processing apparatus or in a program memory of the graphic controller.

A first evaluation of the test data is preferably effected at the level of the test control unit.

Generally, a customary graphic controller is assigned four or eight semiconductor memory devices as video memories. Since the supply and handling system can supply significantly more semiconductor memory devices to the receiving unit, the test parallelism can be increased by a larger number of test assemblies arranged in the receiving unit.

According to a first preferred embodiment of the test apparatus according to the invention, a multiplexer unit is arranged between the test assemblies and the data processing apparatus. The multiplexer unit has a plurality of graphic interfaces to the test control units and a further graphic interface to the data processing apparatus. The multiplexer unit distributes a test program output by the data processing apparatus via the graphic interface or control commands in parallel to the connected test assemblies, or graphics cards. The test assemblies communicate a good/poor information item relative to the tested semiconductor memory devices to the multiplexer unit. The multiplexer unit takes up the result of the test in parallel and forwards it to the data processing apparatus.

According to a further preferred embodiment of the test apparatus according to the invention, as the data processing apparatus, a first motherboard (main board) is provided in the region of the receiving unit. The test assemblies are then arranged on the first motherboard in a simple manner like graphics cards in installation locations provided for graphics cards. A screen for process visualization and a keyboard for operator-controlled process control are connected via further standard interfaces of the data processing apparatus. Further graphics cards may be provided in each case in further motherboards, which are connected via standardised interfaces to the first motherboard of the data processing apparatus and can be controlled by the latter.

The embodiment of the test apparatus using conventional standardized components and assemblies (PC, graphics card, graphic controller) makes it possible to realize rapidly the testing of semiconductor memory devices at least with regard to a speed of a data transfer interface independently of test systems and to adapt it to continually changing application conditions. Components which determine the speed of the semiconductor memory device are tested without complicated conversion of existing, slower tester apparatuses.

The foregoing disclosure of the preferred embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

1. A test method for semiconductor memory devices, comprising:
arranging a plurality of the semiconductor memory devices in test receptacles of a receiving unit by using a supply and handling system;
causing the semiconductor memory devices to output data signals; and
evaluating the data signals using a test apparatus having test control units that are selected from memory control units,
wherein the test control units are a part of the test apparatus.

2. The method as claimed in claim 1, further comprising:
generating, by the test control units, test data;
transferring the test data to the semiconductor memory devices and storing the test data in the semiconductor memory devices;
causing the stored test data to be output as test data signals; and
evaluating the test data signals in the test control units by comparing test data derived from the test data signals with the respectively corresponding test data.

3. The method as claimed in claim 1, wherein the test control units are provided in the interior of a housing of a receiving unit.

4. The method as claimed in claim 3, wherein the test data are generated and assessed in the test control unit by means of a memory test program stored in a memory control program memory respectively assigned to the test control units.

5. The method as claimed in claim 4, wherein
the test control units are provided on test assemblies, which are substantially structurally identical to the memory assemblies,
contact devices of installation locations provided on the test assemblies for the installation of semiconductor memory devices are connected to respectively assigned contact devices of test receptacles, and
the test assemblies are arranged in the receiving unit.

6. The method as claimed in claim 5, wherein the test assemblies and the supply and handling system are connected to a data processing apparatus, which controls a test sequence, and ambient parameters are set in accordance with the test specifications by means of a test program stored in the data processing apparatus in the course of a test of the semiconductor memory devices by means of the supply and handling system.

7. The method as claimed in claim 6, wherein supply voltages required for the operation of the semiconductor memory devices are controlled in the course of testing in accordance with the test specifications by means of voltage sources, which are controlled by at least one of the data processing apparatus and the test control units.

8. The method as claimed in claim 7, wherein
a timing behavior of the test control units is determined,
a test frequency is determined for a test of semiconductor memory devices respectively assigned to a speed sorting, taking account of the measured timing behavior of the respective test control units, at which test frequency semiconductor memory devices that which are to be assigned to the speed sorting still just function taking account of specified deviations, and
a test of the semiconductor memory devices is carried out at the test frequency by means of the test control units.

9. The method as claimed in claim 8, wherein DRAMs having in each case a data strobe terminal for a data strobe signal and having data terminals for bi-directional data signals that are synchronized with the data strobe signal are provided as the semiconductor memory devices to be tested.

10. A test apparatus for testing semiconductor memory devices that are provided together with memory control units for operation on memory assemblies and include a data strobe terminal for a data strobe signal and data terminals for bi-directional data signals, the test apparatus comprising:
at least one test receptacle for receiving a respective one of the semiconductor memory devices in a manner free of soldering;
a supply and handling system for automated population of the test receptacles with the semiconductor memory devices to be tested;
a receiving unit, which imparts a mechanical and electrical interface between the test receptacles and the supply and handling system;
test signal units for outputting, for reception and for evaluation of data signals output by the semiconductor memory devices; and
test control units having substantially the same design as the memory control units and being operable as test signal units.

11. The test apparatus as claimed in claim 10, wherein the test control units are arranged within a housing of a receiving unit.

12. The test apparatus as claimed in claim 11, further comprising
at least one test assembly, which is compatible with a memory assembly and has in each case at least one test control unit and is arranged in the receiving unit, and also connecting lines between respectively correspondingly contact devices of installation locations provided on the test assembly for the semiconductor memory devices and contact devices of the test receptacles.

13. The test apparatus as claimed in claim 12, further comprising a data processing apparatus, which is connected to at least one of the test assemblies via a graphics card interface (AG) and controls a test sequence.

14. The test apparatus as claimed in claim 13, further comprising a multiplexer unit which is arranged between the data processing apparatus and a plurality of test assemblies and multiplies the graphics card interface (AG) of the data processing apparatus.

15. The test apparatus as claimed in claim 14, wherein a first motherboard assigned to the data processing apparatus is arranged in the receiving unit, and the test assemblies are arranged on the first motherboard in installation locations provided for graphics cards.

16. The test apparatus as claimed in claim 15, wherein at least one further motherboard is arranged in the receiving unit and is connected to the first motherboard via a coupling bus.
